(19) United States
(12) Patent Application Publication
(10) Pub. No.: US 2006/0044899 A1
(43) Pub. Date: Mar. 2, 2006

(54) Method and apparatus for destroying flash memory

(76) Inventors: Robert W. Ellis, Phoenix, AZ (US); Alan A. Fitzgerald, Gilbert, AZ (US); Daniel P. Fogelson, Chandler, AZ (US); Kevin Lee Kilzer, Chandler, AZ (US)

Correspondence Address: C. ROBERT VON HELLENS;CAHILL, VON HELLENS & GLAZER P.L.C., 155 PARK ONE,, 2141 E. HIGHLAND AVENUE, PHOENIX, AZ, 85016, US

(21) Appl. No.: 11/212,173

(22) Filed: Aug. 26, 2005

Related U.S. Application Data
(60) Provisional application No. 60/604,953, filed on Aug. 27, 2004.

(51) Int. Cl. G11C 29/00

(52) U.S. Cl. 365/201

(57) ABSTRACT

On command and subject to a fail-safe interlock, a signal is generated to essentially instantaneously destroy the data and/or access to data stored in a flash memory device. Subsequently, the storage memory device is tested for confirmation of destruction of the data and/or access to the data. This cycle is repeated until verification of destruction of the data and/or access to data is achieved.

### CROSS REFERENCE TO RELATED APPLICATIONS

The present application is related to and claims priority of a provisional application entitled “TECHNIQUE AND APPARATUS TO ASSURE PHYSICAL DISABLING OF FLASH MEMORY DEVICE”, filed Aug. 27, 2004, and assigned Ser. No. 60/604,953, by the present joint inventors.

### BACKGROUND OF THE INVENTION

1. Field of the Invention

The present invention relates to destruction of data and/or access to data in a flash memory device and, more particularly, to very rapid destruction of the data and/or access to data in a flash memory device.

2. Description of Related Prior Art

Secure computer systems, whether mounted in aircraft, land based vehicles or above- or below-water vessels presently have electronic equipment of various types and data storage devices relating thereto. Typically, such data storage devices may be flash memories that may be any of a broad family of integrated circuits which are used for non-volatile data storage.

The data stored therein may be classified as confidential or secret information. Should such a computer fall into unauthorized hands, the data stored in the flash memory devices may be retrieved and the secrecy of the attendant data may be compromised. When such a computer is damaged by enemy fire or the like, it is of paramount importance that the data contained in any flash memory devices used as part of operation of the computer be immediately destroyed as there may be little time to attend to such destruction.

The conventional manner for destroying data in a flash memory device involves the process of erasing and overwriting the existing data. This process is time consuming and the requisite time may not be available if the computer is rapidly abandoned due to the nature of the damage suffered. To speed up the erase and re-write process, it may be performed randomly, resulting in some remaining data that includes blank spots and therefore renders the data less useable and more difficult to interpret. Additionally, the erase and re-write sequence may be applied in parallel to all flash memory devices that embody sensitive data. Another existing method is that of weighting the erase/re-write operation to select the flash memory devices in descending order of sensitivity of the data stored therein. While these methods of destruction of data may be relatively rapid, under certain emergency circumstances, there may not be sufficient time to have personnel perform the operations without jeopardizing their safety.

### SUMMARY OF THE INVENTION

The present invention is directed to near instantaneous destruction of data and/or access to data contained in flash memory devices of the type having integrated circuits which are used for non-volatile data storage. The near instantaneous destruction of data and/or access to data in a flash memory device can be achieved by reversing the polarity of the power supply to the flash memory device in order to damage internal connections relating to the power distribution and or in logic circuitry. Another method is that of applying an excessive voltage to the power supply of the flash memory device for the purpose of destroying internal connections of the power distribution and logic circuitry. A further method is to apply voltage and/or current values to the control signals of a flash memory device which voltage and/or current values are outside of the safe operating parameters whereby the control signals can no longer function to permit retrieval of data.

It is therefore a primary object of the present invention to provide methodology and apparatus and an apparatus for near instantaneous destruction of the data and/or access to data stored in a flash memory device.

Another object of the present invention is to provide a method for near instantaneously destroying the ability to retrieve data from a flash memory device.

Yet another object of the present invention is to provide a method and an apparatus for destroying the ability to retrieve data from a flash memory device followed by testing the flash memory device to insure unavailability of the data stored therein.

Still another object of the present invention is to sequentially attempt to destroy availability of data in a flash memory device and testing the flash memory device until confirmation of destruction of the data is achieved.

A further object of the present invention is to provide a fail safe interlock to prevent inadvertent instantaneous destruction of data in a flash memory device.

A yet further object of the present invention is to provide a manually actuated sequence of repetitively destroying the data stored in a flash memory device and testing the ability to retrieve the data until confirmation is received that the data is no longer available.

A still further object of the present invention is to provide a method for destroying the ability of unauthorized personnel from retrieving data from a flash memory device.

These and other objects of the present invention will become apparent to those skilled in the art as the description thereof proceeds.

### BRIEF DESCRIPTION OF THE DRAWINGS

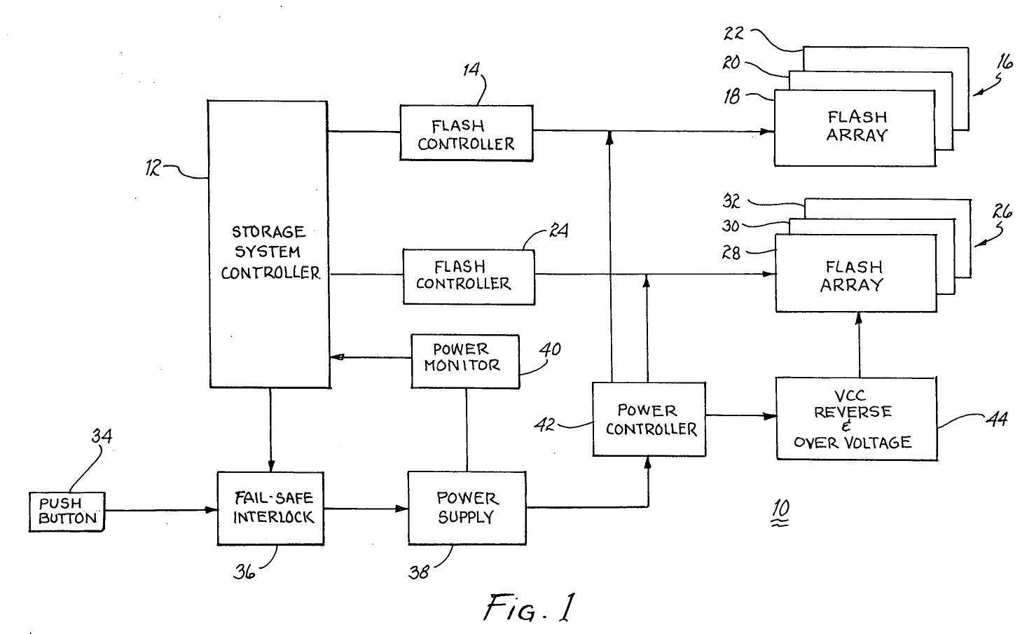

The present invention will be described with greater specificity and clarity with reference to the block diagram shown in FIG. 1.

### DESCRIPTION OF THE PREFERRED EMBODIMENT

The present invention is directed to methodology for essentially instantaneously destroying the data and/or access to the data in a flash memory device of a type within a broad family of integrated circuits which provide for non-volatile data storage. Typically, the stored data will remain in memory even when all power sources have been removed from the flash memory device.

Referring to FIG. 1, there is illustrated a block diagram of circuitry for a system 10 that can be used to bring about essentially instantaneous destruction of or access to data stored in a flash memory device. A storage system controller 12 is connected through a flash controller 14 to an array 16 of flash memory devices 18, 20 and 22. The storage system controller is connected to a further flash controller 24 to control another array 26 of flash memory devices 28, 30 and 32.

Some implementations may find it advantageous to combine the functions of storage controller 12 and flash controllers 14 and 24 into a single control component such as a microprocessor. One skilled in the art will appreciate that combining these functions does not alter the operation of this invention.

To effect destruction of the data and/or access to data stored in arrays 16 and 26, a push button 34 may be actuated. It is to be understood that such a push button may be a key pad, toggle switch or other similarly functioning module or an equivalent electronic signal. To insure against inadvertent or random destruction of the data and/or access to data, a fail-safe interlock 36 may be incorporated. To guard against accidental activation of circuitry for destroying the data, any of several interlock techniques may be used in fail-safe interlock 36. For example, it may require sequential application of input commands. It may require validation by other system status and/or integrity indicators, sometimes known as watch dog devices or system reset signals. It may also require that sufficient power be available to complete the data destruction operation. The fail-safe interlock is interconnected with storage system controller 12 and power supply 38. A power monitor 40 may be incorporated to provide an indication of the status of the power supply to the system storage controller. The power supply provides power to power controller 42 which is interconnected with each of arrays 16, 26 to provide power to each of the attendant flash memory devices. The power controller provides power to a destruction signal generator 44. The destruction signal generator may provide to array 26 power of a reverse polarity or an excessive power level.

As shown in FIG. 1, array 16 of flash memory devices 18, 20 and 22 are considered non-critical with respect to complete and essentially instantaneous destruction of data stored therein in the event of a predetermined event or any of several events. Thus, the data stored therein, if it is to be destroyed, can be destroyed by the conventional erase/re-write methodology.

Flash memory devices 28, 30 and 32, forming array 26, are assumed to contain data of a critical nature that may have to be destroyed essentially instantaneously. To effect such destruction, push button 34 is actuated. Assuming that fail-safe interlock 36 does not detect a condition that would preclude data destruction and that all conditions for such data destruction have been met, power controller 42 transmits a signal to destruction signal generator 44. This destruction signal generator may cause the polarity of the power supply to each of flash memory devices 28, 30 and 32 to be reversed. Such reversal would cause irreversible damage to the internal connections of the power distribution and logic circuitry of each flash memory device.

This destruction occurs essentially instantaneously. Alternatively, the destruction signal generator may cause the power supply to each of the flash memory devices within array 26 to provide an excessive voltage, which would essentially destroy or irreversibly damage the internal connections of the power distribution and logic circuitry.

To insure destruction of the data and/or access to data stored in flash memory devices 28, 30 and 32, each would be interrogated or a command and control signal would be applied to each flash memory device by flash controller 24 to discover whether normal operation was possible. In the event normal operation were possible, the destructive signal generated by destructive signal generator 44 would be repeated and followed by verification that each flash memory device could not perform its normal operation. This cycle would be repeated until verification of the destruction of the stored data and/or access to data is received. It is to be noted that flash controller 14 may perform a similar function in testing each of flash memory devices 18, 20 and 22 in array 16. Verification of destruction of data and/or access to data may also be accomplished by monitoring the voltage and current (total energy) applied during the destruction sequence as the level of voltage and current necessary to destroy the data and/or access to data is known.

An indication of the destruction process or completion may be provided by a light or other indicia of some type.

1. A method for destroying a flash memory device, said method comprising the steps of:
a) applying excessive electrical power to damage the power distribution and logic circuitry associated with the flash memory device;
b) testing the flash memory to confirm destruction; and
c) repeating steps a and b until destruction is verified upon exercise of step b.

2. The method as set forth in claim 1, including the step of providing an interlock to prevent inadvertent exercise of step a.

3. A method for destroying a flash memory device, said method comprising the steps of:
a) applying reverse polarity electrical power to damage the internal connectors of power distribution and logic circuitry associated with the flash memory device;
b) attempting to command and control the flash memory device to determine operability; and
c) repeating steps a and b until destruction is verified by exercise of step b.

4. The method set forth in claim 3, including the step of providing an interlock to prevent inadvertent exercise of step a.

5. A method for destroying a flash memory device, said method comprising the steps of:
a) applying a value of an electrical signal in excess of the operating parameters of the flash memory to attack and destroy the integrated circuit control signals;
b) verifying non operability of the flash memory device after exercise of step a; and
c) repeating steps a and b until verification of non operability is provided by exercise of step b.

6. A method as set forth in claim 5, including the step of providing an interlock to prevent inadvertent exercise of step a.

7. Apparatus for destroying a flash memory device, said apparatus comprising in combination:
a) means for applying excessive electrical power to damage the power distribution and logic circuitry associated with the flash memory device;
b) means for testing the flash memory to confirm destruction; and
c) means for actuating said applying means and said testing means until destruction is verified.

8. The apparatus as set forth in claim 7, including means for providing an interlock to prevent inadvertent actuation of said applying means.

9. Apparatus for destroying a flash memory device, said apparatus comprising in combination:
a) means for applying reverse polarity electrical power to damage the internal connectors of power distribution and logic circuitry associated with the flash memory device;
b) means for attempting to command and control the flash memory device to determine operability; and
c) means for actuating said applying means and said attempting means until destruction is verified.

10. The apparatus as set forth in claim 9, including means for providing an interlock to prevent inadvertent actuation of said applying means.

11. Apparatus for destroying a flash memory device, said apparatus comprising in combination:
a) means for applying a value of an electrical signal in excess of the operating parameters of the flash memory to attack and destroy the integrated circuit control signals;
b) means for verifying non operability of the flash memory device after actuation of said applying means; and
c) means for actuating said applying means and said verifying means until verification of non operability of said flash memory device is provided.

12. The apparatus as set forth in claim 1 1, including means for providing an interlock to prevent inadvertent actuation of said applying means.

13. The method as set forth in claim 1, including the step of verifying the existence of sufficient electrical energy to effect damage to the power distribution and logic circuitry.

14. The method as set forth in claim 13, including the step of reverting to conventional methodology for removing data from a flash memory device in the event said step of verifying indicates a lack of sufficient energy to effect the damage.

15. The method as set forth in claim 3, including the step of verifying the existence of sufficient electrical energy to effect damage to the power distribution and logic circuitry.

16. The method as set forth in claim 15, including the step of reverting to conventional methodology for removing data from a flash memory device in the event said step of verifying indicates a lack of sufficient energy to effect the damage.

17. The method as set forth in claim 5, including the step of verifying the existence of sufficient electrical energy to effect damage to the power distribution and logic circuitry.

18. The method as set forth in claim 17, including the step of reverting to conventional methodology for removing data from a flash memory device in the event said step of verifying indicates a lack of sufficient energy to effect the damage.

19. The apparatus as set forth in claim 7, including means for verifying the existence of sufficient electrical energy to effect damage to the power distribution and logic circuitry.

20. The apparatus as set forth in claim 19, including means for reverting to conventional methodology for removing data from a flash memory device in the event said verifying means indicates a lack of sufficient energy to effect the damage.

21. The apparatus as set forth in claim 9, including means for verifying the existence of sufficient electrical energy to effect damage to the power distribution and logic circuitry.

22. The apparatus as set forth in claim 21, including means for reverting to conventional methodology for removing data from a flash memory device in the event said verifying means indicates a lack of sufficient energy to effect the damage.

23. The apparatus as set forth in claim 11, including means for verifying the existence of sufficient electrical energy to effect damage to the power distribution and logic circuitry.

24. The apparatus as set forth in claim 23, including means for reverting to conventional methodology for removing data from a flash memory device in the event said verifying means indicates a lack of sufficient energy to effect the damage.
